(19) United States
(12) Patent Application Publication
(10) Pub. No.: US 2013/0032940 A1
(43) Pub. Date: Feb. 7, 2013

(54) CHIP PACKAGE STRUCTURE

(71) Applicant: Hung-Che Shen, Hsinchu (TW)

(72) Inventor: Hung-Che Shen, Hsinchu (TW)

(73) Assignee: CHIPMOS TECHNOLOGIES INC., Hsinchu (TW)

(21) Appl. No.: 13/525,354

(22) Filed: Jun. 17, 2012

(30) Foreign Application Priority Data
Aug. 5, 2011 (TW) 100127940

(51) Int. Cl. H01L 23/48

(52) U.S. Cl. 257/737; 257/E23.021

(57) ABSTRACT

A chip package structure includes a chip, a flexible substrate, first leads and second leads. First bumps, second bumps and a seal ring are disposed on an active surface of the chip. The first and second bumps are respectively adjacent to first and second edges of the chip. The seal ring is located between the bumps and the edges. The chip is disposed in a chip mounting region of the flexible substrate. The first and second edges correspond to first and second sides of the chip mounting region respectively. The first leads disposed on the flexible substrate enter the chip mounting region through the first side and extend toward the second side to electrically connect the second bumps respectively. The second leads disposed on the flexible substrate enter the chip mounting region through the second side and extend toward the first side to electrically connect the first bumps respectively.

### CROSS-REFERENCE TO RELATED APPLICATION

This application claims the priority benefit of Taiwan application serial no. 100127940, filed on Aug. 5, 2011. The entirety of the above-mentioned patent application is hereby incorporated by reference herein and made a part of this specification.

### BACKGROUND OF THE INVENTION

1. Field of the Invention

The invention relates to a chip package structure and more particularly to a chip package structure adopting a flexible substrate.

2. Description of Related Art

With the advancement in semiconductor technology, liquid crystal displays (LCDs) now are provided with the advantages such as low power consumption rate, compactness, high resolution, high color saturation, long life-span and so on. Consequently, liquid crystal displays can be widely applied in daily electronic products such as monitors of laptop or desktop computers, televisions, and the like. Moreover, the driver integrated circuits (IC) are the indispensible elements for the liquid crystal displays to operate.

To satisfy the demands for various applications of the LCD driver IC chips, the chips are usually packaged by using the tape automatic bonding (TAB) package technique. The TAB technique is categorized into the chip-on-film (COF) package and the tape carrier package (TCP).

Referring to FIG. 1, specifically, in a chip packaging process adopting the TAB technique, after the flexible substrate 50 is provided with traces/leads and the chip 60 with a plurality of bumps 62 thereupon, an inner lead bonding (ILB) process is performed to make the bumps 62 on the chip 60 and the inner leads 52 on the flexible substrate 50 eutectically bonded and therefore electrically connected. The traces/leads including the inner leads 52 of the conventional flexible substrate 50 are generally formed by etching a copper foil and then plated with a tin layer on the inner leads 52 to facilitate the eutectic bonding between the bumps 62 and the inner leads 52. However, in the eutectic bonding which is usually performed by the thermocompression method, redundant tin plating on the inner lead 52 may induce a tin overflow 70. Since the bonding location of the inner leads 52 and the bumps 62 is close to the edges of the chip 60, the tin overflow 70 is prone to creep along the inner lead 52 to contact with a seal ring/guard ring 80 disposed near the edges of the chip 60, thereby leading to electrical failures such as electric leakage, bridging or short circuit. In addition, as shown in FIG. 2, even if the tin overflow does not occur, the seal ring/guard ring 80 may still contact the inner leads 52 due to the warping or bending of the flexible substrate 50 (ie. edge touch), thereby causing electrical failures such as electric leakage, bridging or short circuit.

### SUMMARY OF THE INVENTION

The invention is directed to a chip package structure capable of reducing the probability of electrical failure caused by unexpected contact between the seal ring disposed around the edges of a chip and the leads on the flexible substrate.

The invention is directed to a chip package structure including a chip, a flexible substrate, a plurality of first leads, and a plurality of second leads. The chip has an active surface. A plurality of first bumps, a plurality of second bumps, and a seal ring are disposed on the active surface. The first bumps are adjacent to a first edge of the chip. The second bumps are adjacent to a second edge opposite to the first edge of the chip. The seal ring is located between the first bumps and the first edge and between the second bumps and the second edge. The flexible substrate has a chip mounting region. The chip mounting region has a first side and a second side that are opposite to each other. The chip is disposed within the chip mounting region and the first edge and the second edge of the chip correspond to the first side and the second side of the chip mounting region respectively. The first leads are disposed on the flexible substrate and enter the chip mounting region through the first side and extend toward the second side to electrically connect the second bumps respectively. The second leads are disposed on the flexible substrate and enter the chip mounting region through the second side and extend toward the first side to electrically connect the first bumps respectively.

In one embodiment of the invention, the chip package structure further includes an encapsulant disposed between the chip and the flexible substrate to cover the first bumps, the second bumps, and the seal ring.

In one embodiment of the invention, each of the first leads and the second leads has an outer end and an inner end. The outer end is distant from the chip mounting region and the inner end terminates in the chip mounting region and connects to the corresponding bump.

In one embodiment of the invention, the first leads and the second leads are arranged in an alternate fashion.

In one embodiment of the invention, the chip package structure further includes a solder resist layer which is located outside the chip mounting region and partially covers the first leads and the second leads.

In one embodiment of the invention, the flexible substrate is suitable for chip-on-film (COF) package and tape carrier package (TCP).

In light of the foregoing, the first leads of the invention enter the chip mounting region through the first side of the chip mounting region and extend toward the second side of the chip mounting region to electrically connect the second bumps adjacent to the second side. The second leads enter the chip mounting region through the second side of the chip mounting region and extend toward the first side of the chip mounting region to electrically connect the first bumps adjacent to the first side. By extending the lead through the chip mounting region to the other side to connect the corresponding bump adjacent to that side, the lead hence would not extend across the edge of the chip adjacent to the bump that the lead is connected to. Thus, when tin overflow occurs during bonding of the leads and the bumps, the excessive tin would not creep along the lead in the direction to contact the seal ring disposed around the edge of the chip, so that electrical failures such as electric leakage or short circuit caused by the bridging of the leads and the seal ring due to the tin overflow can be prevented. Moreover, since the leads extend through the chip mounting region, the strength of the flexible substrate is reinforced so that the flexible substrate can be prevented from denting, warping, and so on. The edge touch issue caused by the warping or bending of the flexible substrate during the chip bonding process can further be avoided. Furthermore, the leads are distributed in the chip mounting region so as to enhance the heat dissipation efficiency of the chip package structure via the high heat conductivity of metal.

In order to make the aforementioned and other features and advantages of the invention more comprehensible, several embodiments accompanied with figures are described in detail below.

### BRIEF DESCRIPTION OF THE DRAWINGS

The accompanying drawings are included to provide further understanding, and are incorporated in and constitute a part of this specification. The drawings illustrate embodiments and, together with the description, serve to explain the principles of the invention.

FIGS. 1 and 2 are schematic diagrams of a conventional tape automatic bonding package structure.

FIG. 3 is a top view of a chip package structure according to an embodiment of the invention.

FIG. 4 is a partial cross-sectional view taken along line A-A′ in the chip package structure shown in FIG. 3.

FIG. 5 is a partial cross-sectional view taken along line B-B′ in the chip package structure shown in FIG. 3.

FIG. 6 is a partial cross-sectional view taken along line C-C′ in the chip package structure shown in FIG. 3.

FIG. 7 is a partial cross-sectional view taken along line D-D′ in the chip package structure shown in FIG. 3.

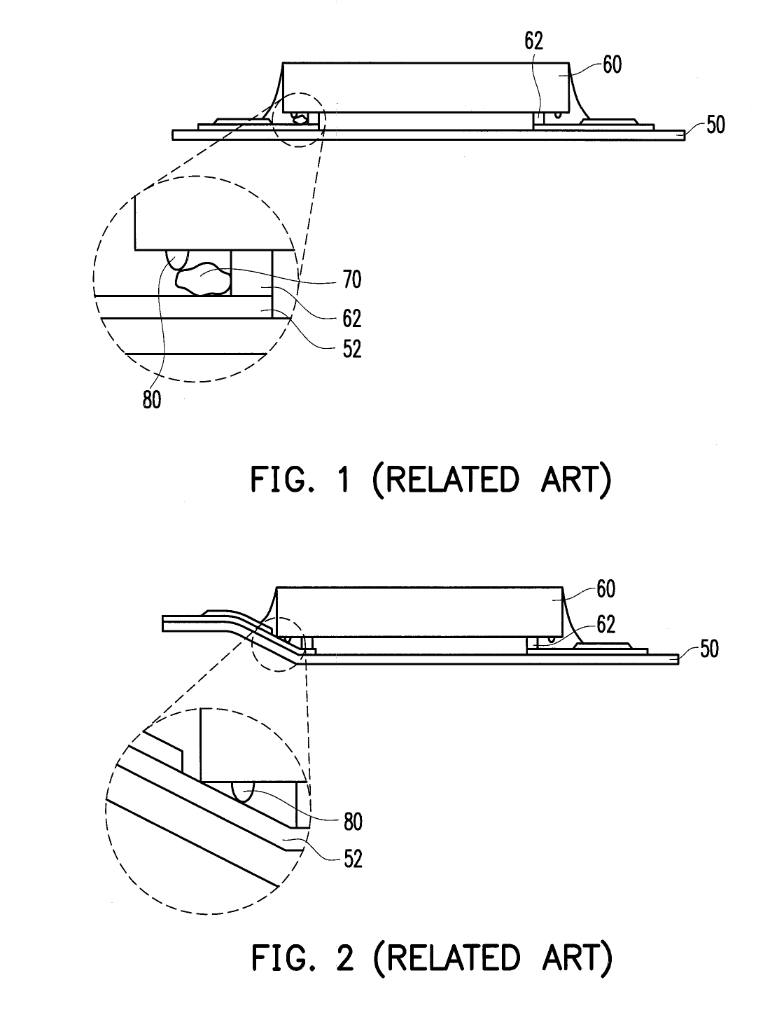

### DESCRIPTION OF EMBODIMENTS

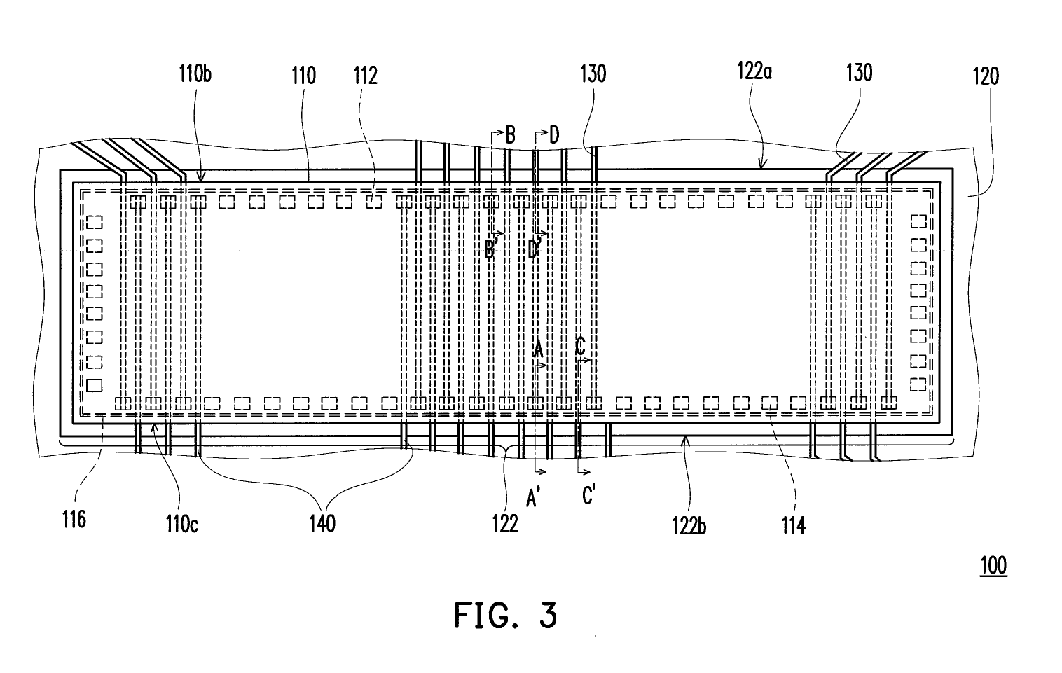

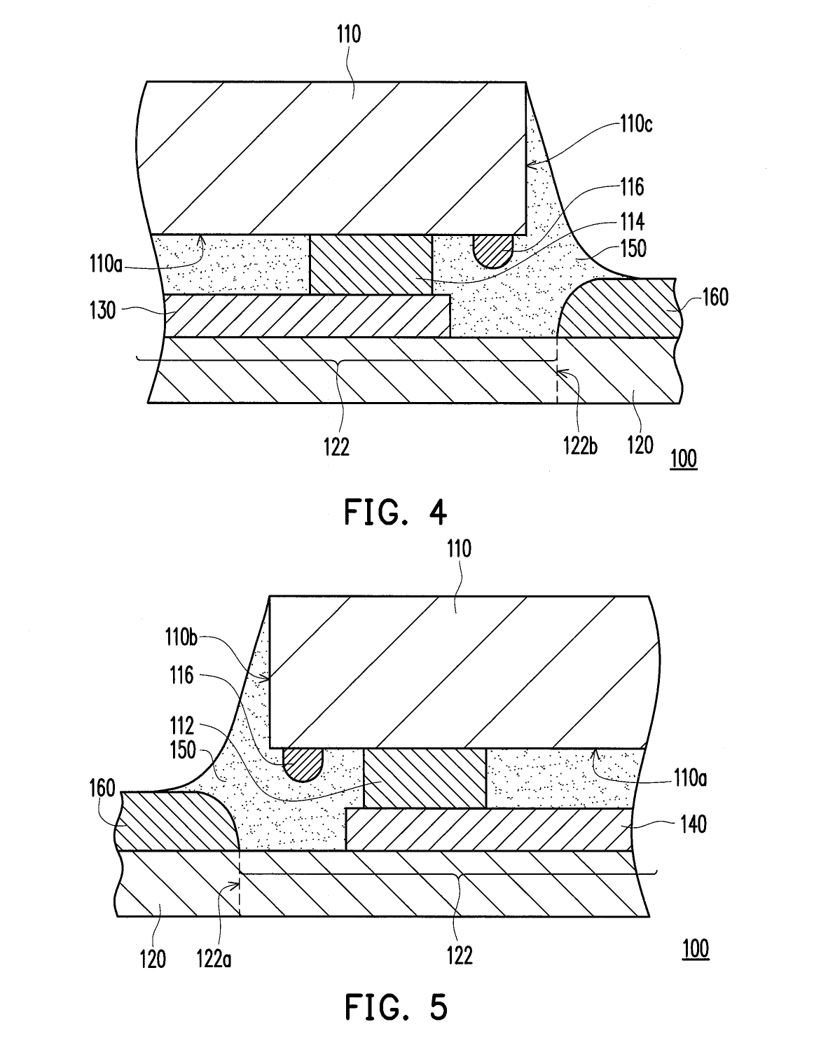

FIG. 3 is a top view of a chip package structure according to an embodiment of the invention. FIG. 4 is a partial cross-sectional view taken along line A-A′ in the chip package structure shown in FIG. 3. FIG. 5 is a partial cross-sectional view taken along line B-B′ in the chip package structure shown in FIG. 3. Referring to FIGS. 3 to 5, a chip package structure 100 of the present embodiment includes a chip 110, a flexible substrate 120, a plurality of first leads 130, and a plurality of second leads 140. The chip 110 has an active surface 110a. A plurality of first bumps 112, a plurality of second bumps 114, and a seal ring 116 are disposed on the active surface 110a. The first bumps 112 are adjacent to a first edge 110b of the chip 110. The second bumps 114 are adjacent to a second edge 110c opposite to the first edge 110b. The seal ring 116 is located between the first bumps 112 and the first edge 110b and between the second bumps 114 and the second edge 110c. In the present embodiment, the seal ring 116 is disposed between the four edges of the chip 110 and the first bumps 112 and the second bumps 114. However, the scope and the shape of the seal ring 116 are not limited thereto. In the view of FIG. 3, a portion of the first leads 130, a portion of the second leads 140, the first bumps 112, the second bumps 114, and the seal ring 116 are shaded by the chip 110 and thus illustrated with dotted lines.

The flexible substrate 120 has a chip mounting region 122 including a first side 122a and a second side 122b that are opposite to each other. The chip 110 is disposed within the chip mounting region 112 and the first edge 110b and the second edge 110c of the chip 110 correspond to the first side 122a and the second side 122b of the chip mounting region 122 respectively. The first leads 130 are disposed on the flexible substrate 120 and enter the chip mounting region 122 through the first side 122a and extend toward the second side 122b to electrically connect the second bumps 114 respectively. The second leads 140 are disposed on the flexible substrate 120 and enter the chip mounting region 122 through the second side 122b and extend toward the first side 122a to electrically connect the first bumps 112 respectively. Accordingly, the first leads 130 do not extend across the second edge 110c of the chip 110 adjacent to the second bumps 114 when bonding with the second bumps 114. In other words, the first leads 130 terminate before the second edge 110c. Similarly, the second leads 140 do not extend across the first edge 110b of the chip 110 adjacent to the first bumps 112 when bonding with the first bumps 112. That is, the second leads 140 terminate before the first edge 110b. Therefore, when tin overflow occurs in an eutectic bonding of the leads 130, 140 and the bumps 112, 114 through a thermocompression process, the excessive tin would not creep along the leads 130, 140 in the direction to contact the seal ring 116 disposed around the edges of the chip 110, so that electrical failures such as electric leakage or short circuit due to unexpected touch of the leads 130, 140 with the seal ring 116 through the tin overflow can be prevented.

The chip package structure 100 further includes a solder resist layer 160 located outside the chip mounting region 122 and partially covering the first leads 130 and the second leads 140 so as to prevent electric short circuit caused by the improper contact between the leads 130, 140 due to foreign materials or lead deformation. The chip package structure 100 of the present embodiment is, for example, but not limited to, a chip-on-film (COF) package. The chip mounting region 122 is defined by an opening of the solder resist layer 160. Not only for the COF package, the flexible substrate 120 is also suitable for tape carrier package (TCP), in which the chip mounting region 122 is defined by a device hole. The material of the flexible substrate 120 is selected from polyimide (PI), polyethylene terephthalate (PET), or other suitable flexible material.

Referring to FIG. 3, a portion of each of the first leads 130 and the second leads 140 distant from the chip mounting region 122 is referred to as an outer end. The outer ends of the leads 130, 140 in the chip package structure 100 are configured to bond the external device(s) (i.e.: a glass panel, a printed circuit board) subsequently. A portion of each of the first leads 130 and the second leads 140 terminating in the chip mounting region 122 and bonded to the corresponding bump (112 or 114) is referred to as an inner end. The inner ends of the first leads 130 and the second leads 140 are eutectically bonded to the corresponding bumps 112, 114 through a thermocompression process or an ultrasonic bonding process. Since the first leads 130 and the second leads 140 extend through the chip mounting region 122, the strength of the flexible substrate 120 is reinforced to prevent the flexible substrate 120 from denting, warping, and so on. The leads 130, 140 touching with the edge of the chip 110 due to the warping or bending of the flexible substrate 120 during the chip bonding process can then be avoided. Moreover, since metals have higher thermal conductivity, the leads 130, 140 extending into the chip mounting region 122 can facilitate the dissipation of the heat generated in the operation of the chip 110, so as to enhance the heat dissipation efficiency of the chip package structure 100. In the present embodiment, the first leads 130 and the second leads 140 are arranged in an alternate fashion to make the overall structure more symmetrical, but the invention is not limited thereto. In other embodiments, the first leads 130 and the second leads 140 can also be arranged in other suitable manner.

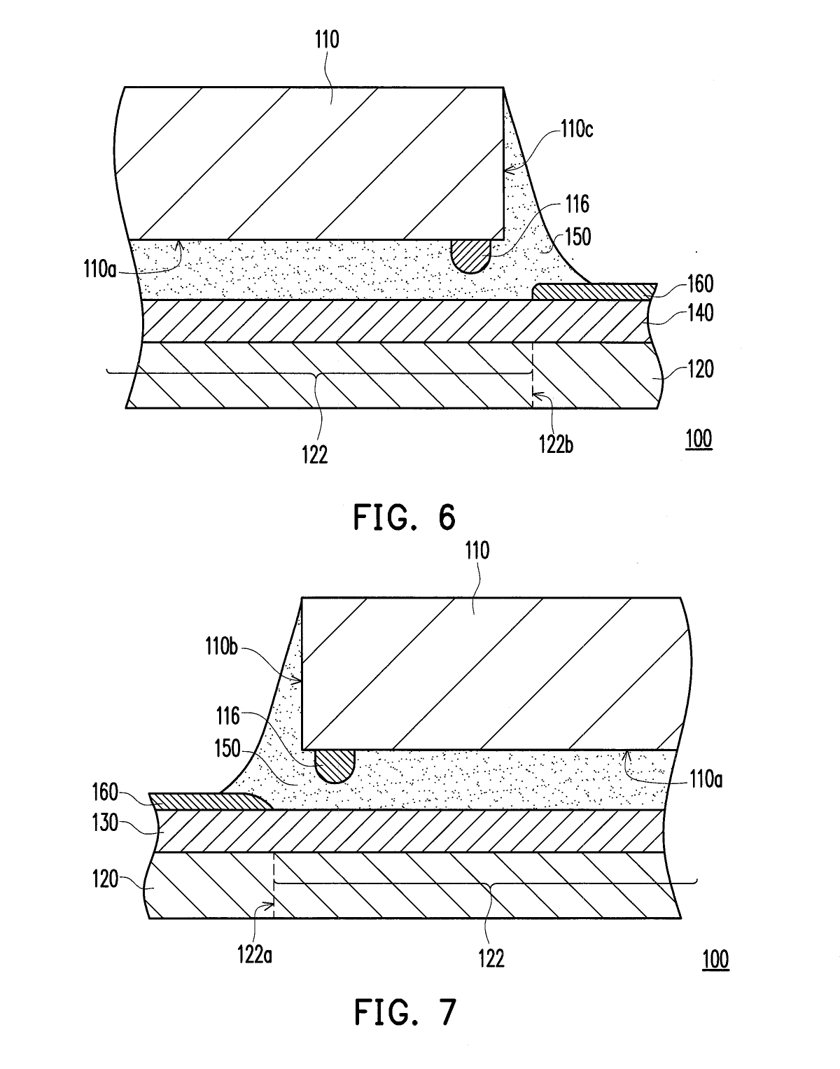

Referring to FIGS. 4 and 5, the chip package structure 100 of the present embodiment further includes an encapsulant 150. The encapsulant 150 is disposed between the chip 110 and the flexible substrate 120 to cover the first bumps 112, the second bumps 114, and the seal ring 116 to prevent invasion of moisture and contaminants, thereby protecting the electrical connections of the bumps 112, 114 and the leads 130, 140. FIG. 6 is a partial cross-sectional view taken along line C-C′ in the chip package structure shown in FIG. 3. FIG. 7 is a partial cross-sectional view taken along line D-D′ in the chip package structure shown in FIG. 3. As depicted in FIG. 6, the second leads 140 extend across the region corresponding to the second edge 110c of the chip 110 but are not bonded to the second bumps 114 disposed near the second edge 110c of the chip 110. The tin overflow thus would not happen so that the short circuit resulted from the bridging of the seal ring 116 and the leads due to the tin overflow can be avoided. Similarly, as depicted in FIG. 7, the first leads 130 extend across the region corresponding to the first edge 110b of the chip 110 but are not bonded to the first bumps 112 disposed near the first edge 110b of the chip 110. The tin overflow thus would not happen so that the short circuit resulted from the bridging of the seal ring 116 and the leads due to the tin overflow can be avoided.

In summary, the first leads of the invention enter the chip mounting region from the first side of the chip mounting region and extend toward the second side of the chip mounting region to electrically connect the second bumps adjacent to the second side. The second leads enter the chip mounting region from the second side of the chip mounting region and extend toward the first side of the chip mounting region to electrically connect the first bumps adjacent to the first side. By extending the lead through the chip mounting region to the other side to connect the corresponding bump adjacent to that side, the lead hence would not extend across the edge of the chip adjacent to the bump that the lead is connected to. Hence, when tin overflow occurs during bonding of the leads and the bumps, the excessive tin would not creep along the lead in the direction to contact the seal ring disposed around the edge of the chip, so that electrical failures such as electric leakage or short circuit caused by the bridging of the leads and the seal ring due to the tin overflow can be prevented. Moreover, since the leads extend through the chip mounting region, the strength of the flexible substrate is reinforced so that the flexible substrate can be prevented from denting, warping, and so on. The edge touch issue caused by the warping or bending of the flexible substrate during the chip bonding process can further be avoided. Furthermore, the leads are distributed in the chip mounting region so as to enhance the heat dissipation efficiency of the chip package structure via the high heat conductivity of metal.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A chip package structure, comprising:
a chip, having an active surface with a plurality of first bumps, a plurality of second bumps, and a seal ring disposed thereon, the first bumps being adjacent to a first edge of the chip, the second bumps being adjacent to a second edge opposite to the first edge of the chip, and the seal ring being located between the first bumps and the first edge and between the second bumps and the second edge;
a flexible substrate, having a chip mounting region, wherein the chip mounting region has a first side and a second side opposite to each other, the chip is disposed within the chip mounting region and the first edge and the second edge of the chip correspond to the first side and the second side of the chip mounting region respectively;
a plurality of first leads, disposed on the flexible substrate and entering the chip mounting region through the first side and extending toward the second side to electrically connect the second bumps respectively; and
a plurality of second leads, disposed on the flexible substrate and entering the chip mounting region through the second side and extending toward the first side to electrically connect the first bumps respectively.

2. The chip package structure as claimed in claim 1, further comprising an encapsulant disposed between the chip and the flexible substrate to cover the first bumps, the second bumps, and the seal ring.

3. The chip package structure as claimed in claim 1, wherein each of the first leads and the second leads has an outer end and an inner end, the outer end is distant from the chip mounting region and the inner end terminates in the chip mounting region and connects to the corresponding bump.

4. The chip package structure as claimed in claim 1, wherein the first leads and the second leads are arranged in an alternate fashion.

5. The chip package structure as claimed in claim 1, further comprising a solder resist layer located outside the chip mounting region and partially covering the first leads and the second leads.

6. The chip package structure as claimed in claim 1, wherein the flexible substrate is suitable for chip-on-film package and tape carrier package.
